(19) United States
(12) Patent Application Publication
(10) Pub. No.: US 2011/0151263 A1
(43) Pub. Date: Jun. 23, 2011

(54) MULTILAYER GROWTH BY GAS PHASE DEPOSITION

(76) Inventors: Matthew R. LINFORD, Orem, UT (US); David S. JENSEN, Provo, UT (US); Feng ZHANG, Provo, UT (US)

(21) Appl. No.: 12/943,807

(22) Filed: Nov. 10, 2010

Related U.S. Application Data
(60) Provisional application No. 61/280,866, filed on Nov. 10, 2009.

(51) Int. Cl. C23C 16/44; B32B 27/38; B32B 27/40; B32B 27/28

(52) U.S. Cl. 428/413; 427/255.7; 427/255.6; 428/423.1; 428/704

(57) ABSTRACT

A multilayer system where intermediate well bonded and cross-linked layers provide attachment for a finishing layer with desired reactive sites.

### CROSS REFERENCE TO RELATED APPLICATIONS

Priority is claimed from U.S. Provisional Patent Application 61/280,866, filed Nov. 10, 2009, which is hereby incorporated by reference

### BACKGROUND

Substrates used in various applications are coated to provide desired surface properties. There is a continued need for methods that apply such coating that provide strongly bonded coatings and the ability to tailor the reactivity or non-reactivity of the surface. A problem that can occur in existing coatings, such as those used in chromatography, is that the bond between the coating and the substrate fails. Many of these coating systems use strong covalent and ionic bonds, but under conditions of use, even if a small number the bonds may fail, leading to gaps in the coating that expose the substrate surface. This can be aggravated if the unbonded coating chemical has any solubility in the system. This uncovered substrate gaps may introduce reactivity to the system that potentially compromises or interferes with the function of the coating.

### SUMMARY

An aspect of the invention is a coating upon a substrate that is useful in chromatography and other applications. The coating is attached to the substrate with strong ionic or covalent bonds. However, the coating system is also highly cross-linked. Accordingly should a bond fail, the coating is maintained since adjacent bonds hold it in place. Even in the event, several bonds should fail, the coating, which is essentially a very large cross-linked molecule, is very insoluble because of its size. The result is a coating that is very resistant to failure under a wide range of operating conditions.

Another aspect the ability to tailor the thickness of the coating, either by applying multiple layers, or by choosing the particular coating chemicals. The final or active layer can be easily determined by a final application with a finishing layer having the desired activity.

An aspect is a process for making homogeneous multilayers on substrates that either have active chemical sites or can be modified to contain active chemical sites. A gas phase deposition is used as the main tool to deposit multilayers onto a variety of different substrates. In an aspect, the process is as follows:

(1) Chemical A is gas-phase deposited onto a substrate.

(2) Another chemical, chemical B, that can react with chemical A is deposited to add another layer.

(3) Chemicals C is deposited to provide a finishing layer, or to form the final surface with the desired activity, by reacting with reaction sites on deposited Chemical B. Depending upon the chosen chemistry, Chemical C may be used to form an intermediate layer, which is then used for deposition by reacting with Chemical D, which forms the finishing layer.

Steps (1) and (2) can be conducted once or repeated if a thicker layer is dersire before deposition of C. The chemicals A, B, C, and D are evaporable, in the gas phase at the conditions of the reaction. Deposition conditions and the chemical are chosen to provide the suitable deposition reactions in the gas-phase.

For step (1), the substrate may be silicon, glass, metals, ceramics, silica, aluminum, titanium, zirconia, or any other materials that can be activated to bond with chemical A. Chemical A can comprise one or a mixture from any suitable chemical can be chosen from silanes with active groups (e.g., amine, succinic anhydride, gluteric anhydride, epoxy, isocyanate, alcohol, thioisocynates, and the like), or other bifunctional, trifunctional, or tetrafunctional molecules with multiple amines or multiple isocyanates, or combinations of other reactive groups as discussed above. Chemical A can also comprise a monofunctional or bifunctional isocynate or an amine containing molecule. A suitable Chemical A is a amine, epoxide, or isocyanate with at least two functional groups. This allows for cross-linking in the deposited layer, while also providing unreacted groups for bonding the Chemical B.

For step (2), Chemical B can be any evaporable chemical that contains a functional group that can react with molecule A thus tethering the two molecules together by means of a covalent or electrostatic bond. Chemical B should be a molecule that under reasonable temperature can react with A.

For step (3) C and/or D must contain a reactive heteroatom or moiety that can either react with A or B. Either can be a mono- or di-functional molecule that can react with available functional groups from either/or A and/or B. Chemical C may be the same or different from Chemical A, and may provide the finished surface or function as an intermediate bonding layer of deposition of a Chemical D.

As the layers are applied, the gas-phase chemical will react with the previously applied layers. For example, B will reactive with A, and C will react with B, but may also react with any remaining active sites of A. In addition, the gas-deposited chemicals in Chemical A, B, C will react with each other during deposition, thus creating a cross-linked system. Available active sites will remain unreacted to provide active sites for reaction with layers applied subsequently. In the final product a reaction product of the substrate and the applied chemicals, in the form of a multilayers that are with covalently or ionically bonded, and that are highly cross-linked within layers and between layers.

The method for applying Chemicals A, B, C, and D is by a gas-phase chemical deposition or chemical vapor deposition. Such methods are well known. The exact operating conditions and the chemicals chosen are selected where the chemical in the vapor phase and stable, and can be reliably contacted with the substrate for reaction on deposition with the substrate.

Multilayer growth can be important for semiconductor fabrication, biological adsorption, and chromatography and for new materials development.

Types and Examples of Molecules:

Exemplary molecules that can function as A, B, or C, include.

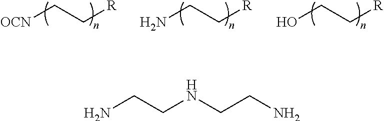

Where R can represent: isocynate, alcohol, amine, thioisocynate, acid chloride, ketone, aldehyde, hydrogen, a charged specie, e.g., sulfonate (—SO₃), phosphate (—PO₄), carbonate (—CO₂).

Suitable chemicals also include any suitable selected from a triamine, a diamine, a tetraamine, a diisocyanate, a triisocyanate, a diepoxide, a triepoxide, a diacid chloride, a triacid chloride. Particular compounds are diethylenetriamine and tris (2-amino ethyl) amine. To promote cross-linking in the layer, at least a portion of Chemical A or Chemical B is a compound with more than two functional groups that can participate in cross-linking reactions, as well as A to B reactions.

The final layer is a finishing layer, Chemical C or D is reactive with the underlying layers and also contains groups that provides the desired reactivity of the final layer, and can be any suitable such group. The finishing layer chemical may also be selected to provide no reactivity. Examples include mono amines, epoxides, or isocyantes (for reaction with the underlying layers) with alkyl chains, and may include reactive thiol groups, For chromatography it may contain an alkyl chain. For ion chromatography or other type of chromatography it may an amine group, sulfonate group, or nitro group.

The present invention provides the following advantages over previous layered systems;
The final active sites are bonded to the substrate by covalent or ionic bondings through layers that are not only firmly bonded but cross-linked to provide a stable and robust attachment
The layer can be built up to any desired thickness, allowing built up, relatively thick layers for such application as microchip fabrication, or thin layers for such applications as chromatography. As an example, thicker layers may be applied for small molecule separations. Thinner layers will be used for chromatographic separations of macromolecule, e.g. proteins, biomolecules. Thinner layers provide modest retention of macromolecules.

### BRIEF DESCRIPTION OF DRAWINGS

FIG. 1 shows the application of a layer on a substrate as an initial step in the formation of a multilayer system.

FIG. 2 shows the application of a layer on a substrate as an initial step in the formation of a multilayer system.

FIGS. 3A, and 3B show reaction steps for the formation of a multilayer system.

FIGS. 4A, 4B, and 4C show reaction steps for the formation of a multilayer system.

FIGS. 5A, 5B, and 5C show reaction steps for the formation of a multilayer system.

FIG. 6 illustrates repeating reaction steps to obtain a desired thickness of a multilayer system.

FIG. 7 is a graph showing thickness of a multilayer system v number of layers.

FIG. 8 is a graph showing thickness of a multilayer system v number of layers.

### DETAILED DESCRIPTION

### Exemplary Applications

Semiconductor

Surface functionalization can be used in the semiconductor industry. The system presented here can be used to allow for precise placement of certain types of metals or metal ions that can react with heteroatoms present on the surface, e.g., a difunctional molecule used in the finishing layer can have a chemical moiety that can react or interact with a metal or metal ion. The chemical for the finishing layer contains at one end a reactive group, i.e., amino or isocynate to react with the underlaying layer formed by Chemical A or B. The other functional group being, for example, a thiol to provide activity for reaction of the metal or metal ion.

The reactive amino or isocyante can react with either the surface layer silanols (chemical A) or a heteroatom (on an underlying layer from Chemical C or Chemical) on the already functionalized surface. The free thiol groups then can further reacted with gold, silver, copper, or other types of noble metals nanodots; thus, allowing for the placement of nanodot materials.

Chromatography

The multilayer system can be applied to chromatography to provide a functionalized surface that will offer different chemical selectivity. This process will provide a highly crossed-link stationary phase. Typical substrates for chromatography are; silica, alumina, zirconia, and titania. The mentioned substrates contain surface moieties (usually OH groups) that can react either with amines or isocynates as shown in Examples 1 and 2.

### Example 1

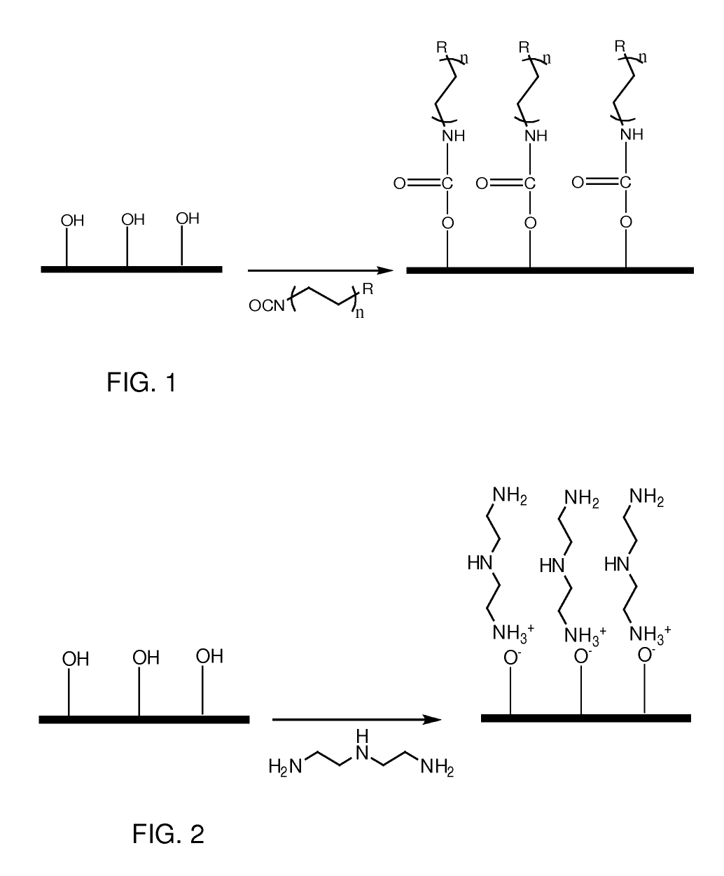

An example of the application of Chemical A to start application of a multilayer system is shown in FIG. 1. A substrates with —OH reactive sites is reacted with an isocyanate.

R can be a carbon chain where n is from 1 to 30, and R is a charged specie for cantionic/anionic chromatograpy, or an isocyanate or thioisocyante.

### Example 2

Another example of the application of chemical A for formation of is multilayer system is shown in FIG. 2 where chemical A is a triamine. Since the surface alcohols are acidic they can form ionic bonds with triamine. Further, the free amines, the —NH₂ functional groups, can react to chemicals, such as those with isocyanate, groups, to make a bonded and cross-linked layer.

### Example 3

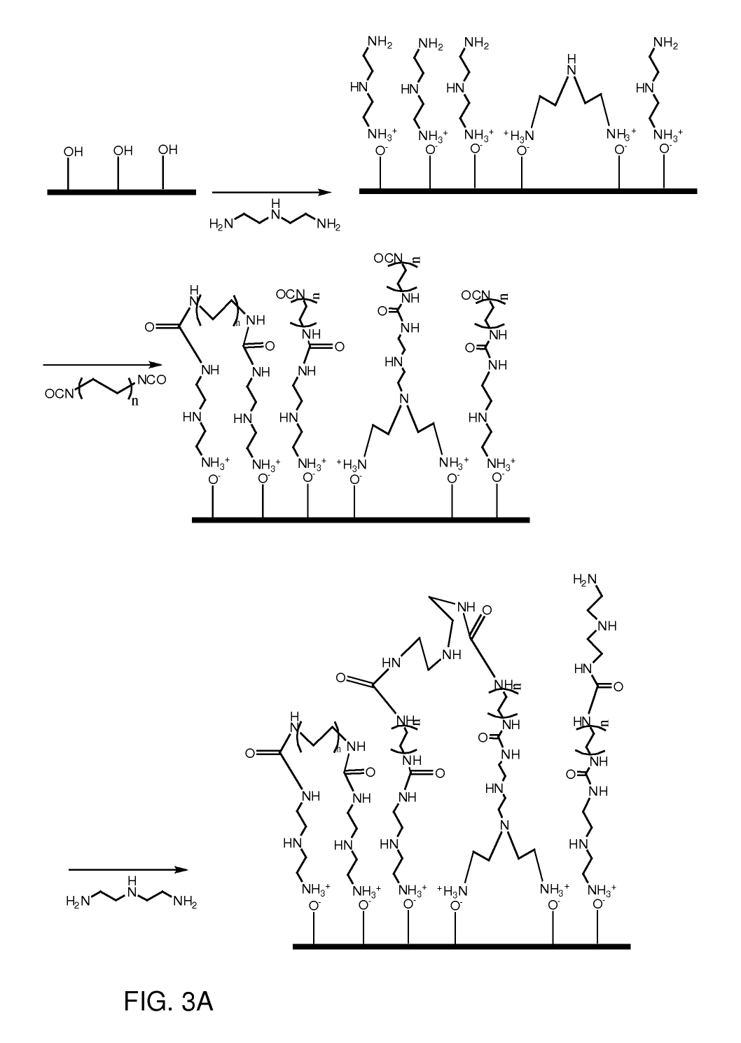

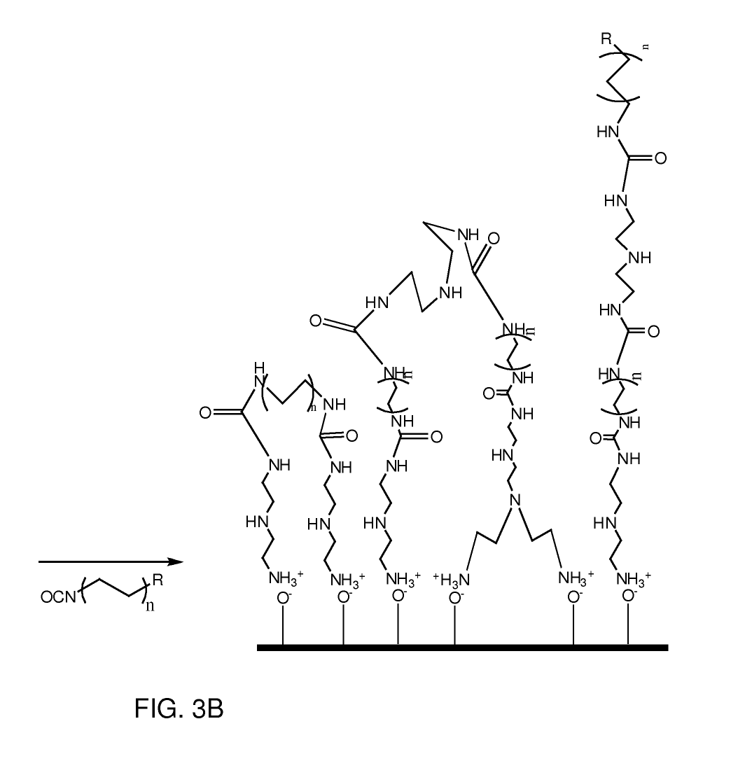

An amino-terminated monolayer as in Example 2 can react with a chemical B, an isocyanate, to create a crossed linked material that will be stable under acidic conditions. The monolayer is applied and reacted as shown in FIG. 3A. The AB multilayer is then reacted with a triamine (the same as chemical A), which is then reacted with an chemical C with an terminal reactive group as shown in FIG. 3B.

This multilayer system can be characterized as ABCD where C=A, where A=triamine, B=diisocyanate, D=a monoisocyanate or mono epoxide with an alkyl chain of length 2-30 carbon units. This method produces a stationary phase that is highly cross-linked which can be attributed to either the di-isocyanate or triamine. Further A and B layers can similarly be applied to form AB)ₙCD or (AB)ₙC multilayer systems, where n is 2 greater.

### Example 4

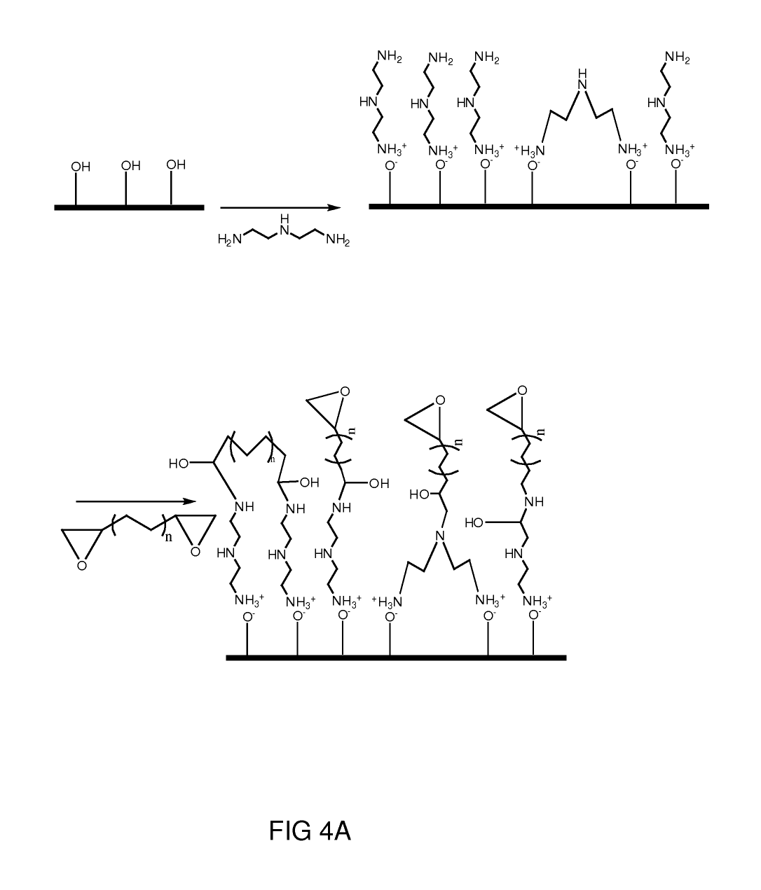

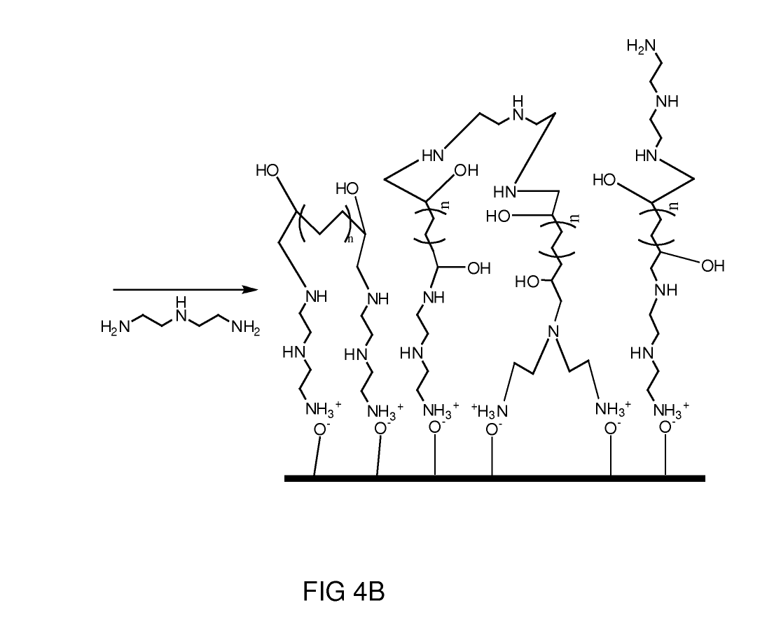

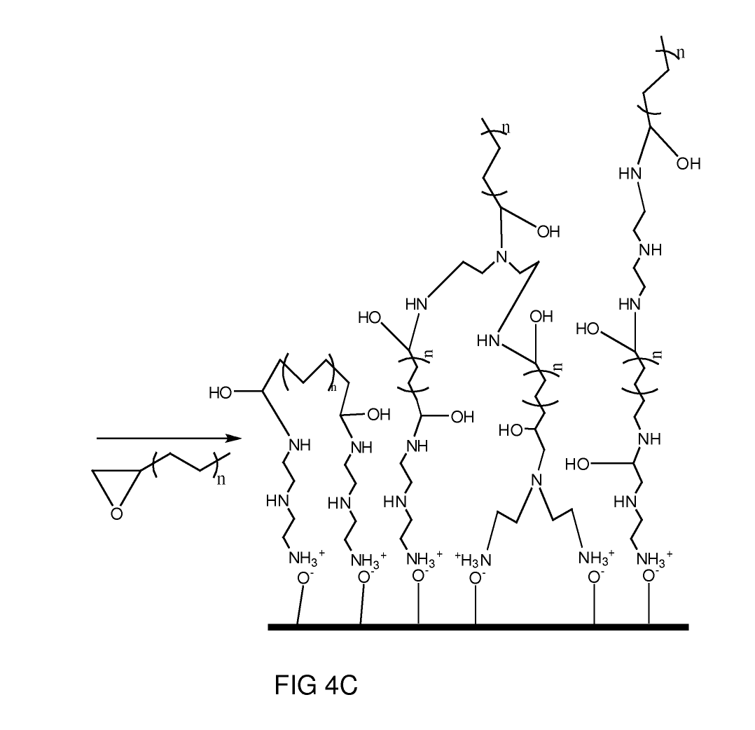

An amino-terminated monolayer as in Example 2 can react with a chemical B, an di-epoxide, to create a crossed linked material that will be stable under acidic conditions as shown in FIG. 4A. This can be further reacted, as shown if FIG. 4B with a triamine, which is in turn, as shown in FIG. 4C, reacted with a mono epoxide.

The resulting multilayer system can be characterized as ABCD where A=triamine, B=diepoxide, C=A; D=a mono epoxide with an alkyl chain of length 2-30 carbon units. This method produces a stationary phase that is highly cross-linked which can be attributed to either the di-epoxide or triamine.

### Example 5

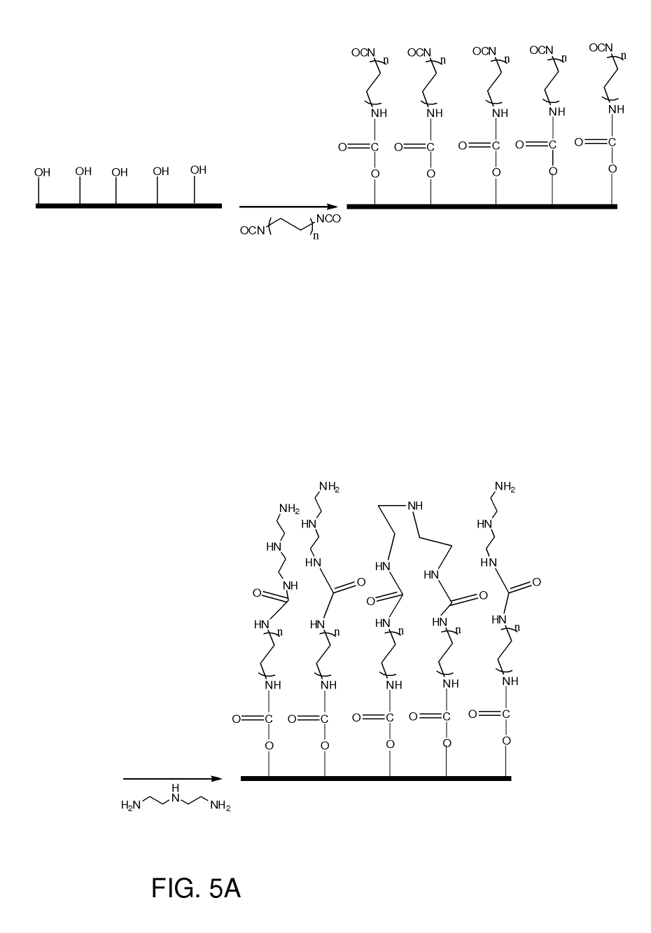

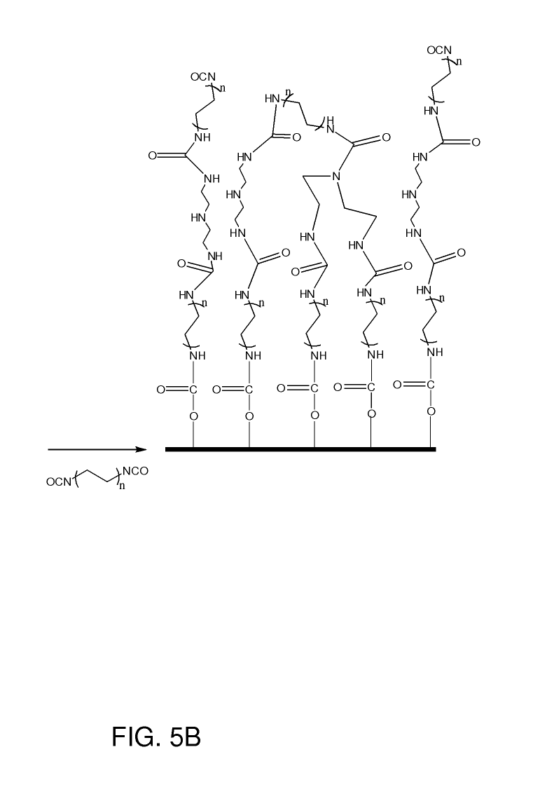

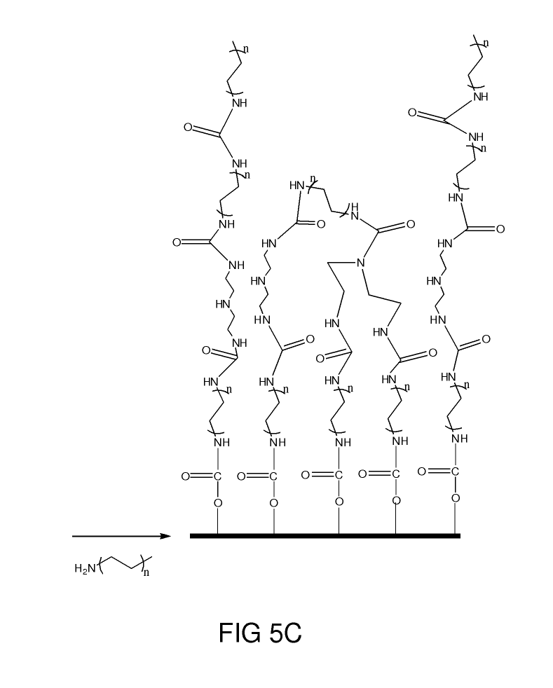

The isocyanate-terminated monolayer as in Example 1 can react with a chemical B, an amine to create a crossed linked material that will be stable under acidic conditions as shown in FIG. 5A, FIG. 5B, and FIG. 5C.

The isocyanate-terminated monlayer is reacted with, chemical B, an amine to form a cross-linked amine terminated layer, which is in turn reacted, as shown in FIG. 5B, with an isocyanate (the same as chemical A), which is in turn reacted, as shown in FIG. 5C with Chemical C, a monoamine.

This multilayer system can be characterized as ABCD, where A=di-isocyanate, B=triamine, C=A, D=mono amine with an alkyl chain of length 2-30 carbon units. This method produces a stationary phase that is highly cross-linked which can be attributed to either the di-isocyanate or triamine.

### Example 6

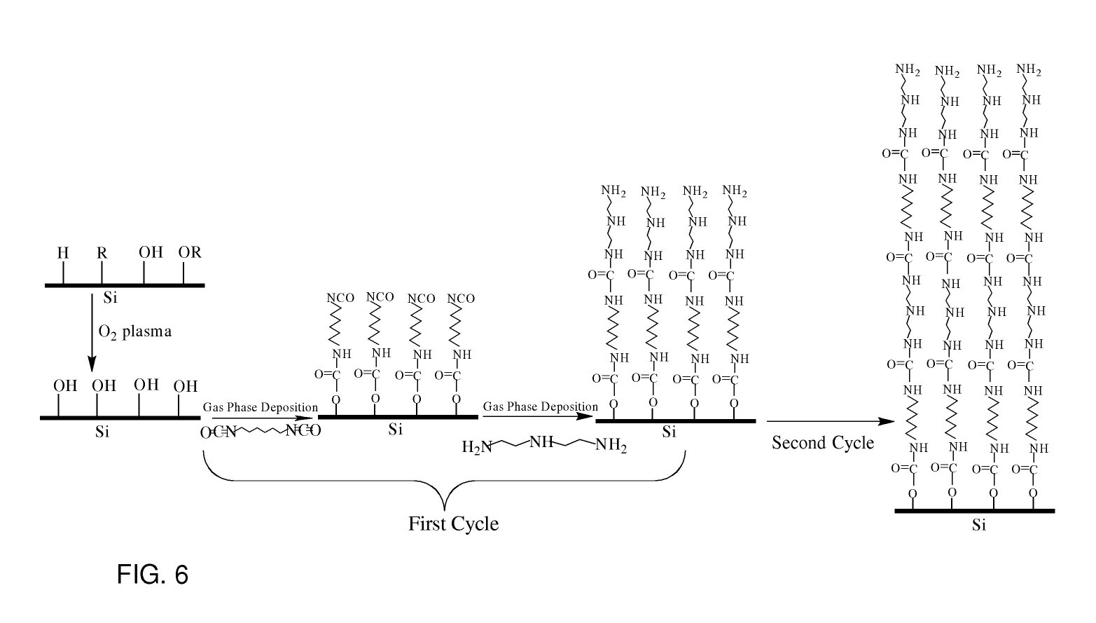

This example shows, how application of layers A and B can be repeated to form a multilayer of desired thickness. A multilayer coating was applied is a silicon substrate. With reference to FIG. 6, the silicon substrate was treated or activated with oxygen plasma to create ao surface with —OH radicals.

A first cycle was conducted by reacting the —OH radicals with a Chemical A, a diisocyante(1,6-diisocyanatohexane). The diioscyate surface was then treated with a Chemical B, a triamine (diethylenetriamine). Both coatings were accomplished using conventional gas phase coating techniques

After the first cycle, and second cycle was conducted using essentially the same reactants and conditions as in the first cycle, using the same Chemical A and Chemical B.

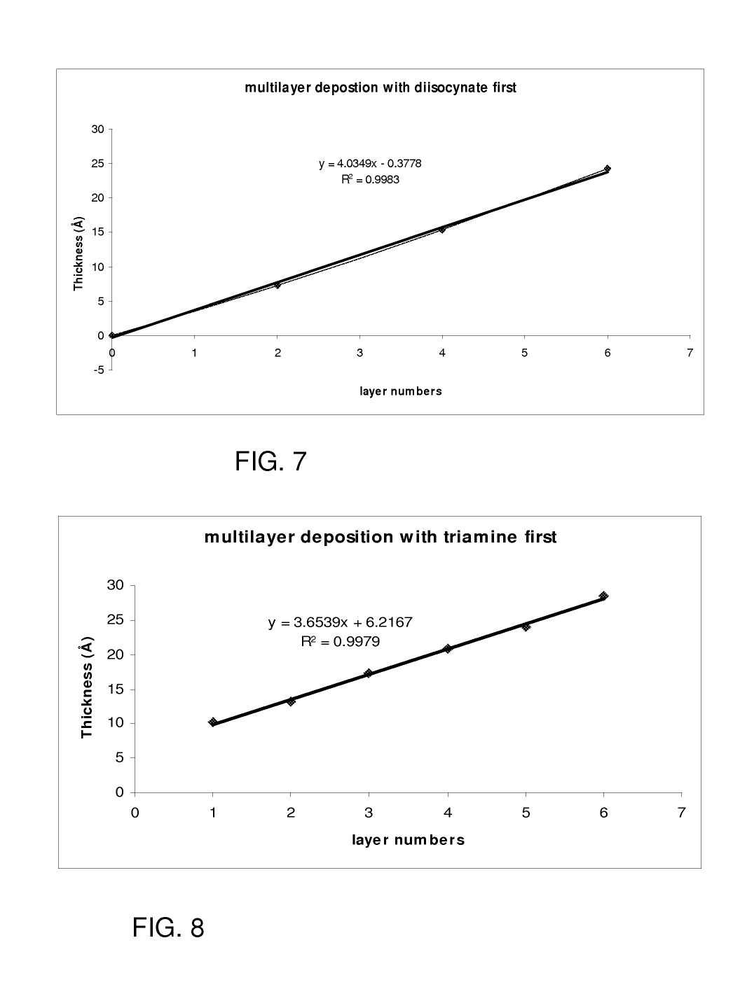

Further cycles were conducted in the same way. After selected cycles thickness was measured using spectroscopic ellipsometry. FIG. 7 is a graph showing the results of the thickness measurements for up to 6 layers. This last multilayer system can be characterized as ABABABABABAB. Each layer number includes both a diisocyanate and a triamine deposition.

Chemical B can be the final layer if it provides the desired reactivity. But, as above, the final layer may be a Chemical D to provide the desired reactivity.

### Example 7

A multilayer system was made, essentially as in Example 6, except Chemical A was the triamine, and Chemical B was the diiosocycante. The cycle was repeated. FIG. 8 shows the thickness measurements of the resulting multilayer systems from the growth of diethylenetriamine and 1,6-diisocyanatohexane layers. The triamine was deposited first, then the diisocyanate was deposited. This cycle is repeated until a suitable thickness is obtained. Each layer number includes both a diisocyanate and a triamine deposition.

What is claimed is:

1. A method for applying a coating to a substrate, the method comprising:
(a) coating the substrate by reacting active sites on the substrate with Chemical A from the gas phase;
(b) coating the substrate reacted with Chemical A by reacting with Chemical B from the gas phase;
Chemical A having functional groups for reaction with the active sites on the substrate, and for cross-linking reactions and for reaction with Chemical B to form a cross-linked layer attached to the substrate, at least a portion of either or both of Chemical A and Chemical B comprising compounds with at least three functional groups that participate in cross-linking and Chemical A to Chemical B reactions;
(c) coating the substrate with a finishing layer by reacting the cross-linked layer with Chemical C from the gas-phase;
where Chemical C is reactive with functional groups in the cross-linked layer,

2. The method of claim 1 additionally comprising (d) coating the substrate by with Chemical D from the gas phase; wherein Chemical D has functional groups that are reactive with function groups in the layer from Chemical C, and where Chemical D has structure to impart selected reactivity to the surface.

3. The method of claim 1 additionally comprising after step (b) (a1) reacting the surface with Chemical A from the vapor phase, and (b1) reacting the surface with Chemical B, where (a1) and (b1) are conducted one or more times before step (c).

4. The method of claim 1 wherein Chemical C is the same as Chemical A.

5. The method of claim 1 wherein Chemicals A and B are different and one or a mixture of a triamine, a diamine, a tetraamine, a diisocyanate, a triisocyanate, a diepoxide, a triepoxide, a diacid chloride, a triacid chloride.

6. The method of claim 1 wherein Chemicals A and B are different and contain epoxide functional groups, isocyanate functional groups, or amine functional groups.

7. The method of claim 1 wherein either Chemical A or Chemical B comprises diethylenetriamine or tris (2-amino ethyl)amine.

8. The method of claim 1 wherein Chemical A or Chemical C contain functions selected from socynate, alcohol, amine, thioisocynate, acid chloride, ketone, aldehyde, hydrogen, sulfonate, phosphate, and carbonate

9. The method of claim 1 wherein the substrate is activated to provide the active sites.

10. The method of claim 1 wherein Chemical A comprises a triamine and Chemical B comprises a multifunctional epoxide or isocyanate.

11. The method of claim 1 wherein Chemical C provides a final functionalalized surface with chemical selectivity that is suitable for chromatographic separation applications.

12. The method of claim 2 wherein Chemical D provides a final functionalalized surface with chemical selectivity that is suitable for chromatographic separation applications.

13. The method of claim 1 wherein Chemical C comprises functional groups selected from amines, epoxides, or isocyantes.

14. The method of claim 1 wherein Chemical C comprises one or groups selected from alkyl chains, reactive thiol groups, amine groups, sulfonate groups, or nitro groups.

15. The method of claim 2 wherein Chemical D comprises one or groups selected from alkyl chains, reactive thiol groups, amine groups, sulfonate groups, or nitro groups.

16. A layered article comprising a substrate, and a chemically bonded layer which is the reaction product of Chemical A and Chemical B wherein Chemicals A and B are different and separately gas-deposited, the bonded layer having cross-linking in the layer, and bonding between Chemical A and Chemical B, and
Chemical C that is gas-deposited on the cross-linked and bonded layer of Chemical A and B.

17. The article of claim 16 additional comprising a functionalized surface with chemical selectivity provided by Chemical C.

18. The article of claim 17 wherein Chemical A and Chemical B have different functional groups selected from amine, epoxide, and isocyanate.

19. The article of claim 16 additionally comprising a functionalized surface with chemical selectivity provided by Chemical D reacted with the reaction product of Chemicals A, B, and C.

20. The article of claim 16 where Chemical A and Chemical C are the same.
